(19) United States
(12) Patent Application Publication
(10) Pub. No.: US 2012/0205771 A1
(43) Pub. Date: Aug. 16, 2012

(54) SCHOTTKY DIODE WITH LOW FORWARD VOLTAGE DROP

(75) Inventors: Chiun-Yen TUNG, Kaohsiung City (TW); Kai-Ying WANG, Kaohsiung City (TW); Chia-Ling LU, Kaohsiung City (TW); Kuo-Hsien WU, Kaohsiung City (TW); Kun-Hsien CHEN, Kaohsiung City (TW)

(73) Assignee: PYNMAX TECHNOLOGY CO., LTD., Dongguan (CN)

(21) Appl. No.: 13/186,496

(22) Filed: Jul. 20, 2011

(30) Foreign Application Priority Data
Feb. 11, 2011 (TW) 100202613

(51) Int. Cl. H01L 29/872

(52) U.S. Cl. 257/471; 257/E29.338

(57) ABSTRACT

A Schottky diode with a low forward voltage drop has an N− type doped drift layer formed on an N+ type doped layer. The N− type doped drift layer has a first surface with a protection ring inside which is a P-type doped area. The N− type doped drift layer surface is further formed with an oxide layer and a metal layer. The contact region between the metal layer and the N− type doped drift layer and the P-type doped area forms a Schottky barrier. The height of the Schottky barrier is lower than the surface of the N− type doped drift layer, thereby reducing the thickness of the N− type doped drift layer under the Schottky barrier. This configuration reduces the forward voltage drop of the Schottky barrier.

### BACKGROUND OF THE INVENTION

1. Field of the Invention

The invention relates to a Schottky barrier and, in particular, to a Schottky barrier with a low forward voltage drop.

2. Description of Related Art

With reference to FIG. 6, a conventional Schottky diode mainly has an N− type doped drift layer 81 formed on an N+ type doped layer 80. The N− type doped drift layer 81 is formed with an embedded protection ring 82 in which a P-type doped area is formed. The surface of the N− type doped drift layer 81 is further formed with an oxide layer 83 and a metal layer 84. The contact region between the metal layer 84 and the N− type doped drift layer 81 and the P-type doped area forms a Schottky barrier 85. Moreover, the bottom surface of the N+ type doped layer 80 is formed with a metal layer as a bottom electrode 86.

In the above-mentioned structure, free electrons in the N− type doped drift layer 81 have a lower energy level than those in the metal layer 84. Without a bias, the electrons in the N− type doped drift layer 81 cannot move to the metal layer 84. When a forward bias is imposed, the free electrons in the N− type doped drift layer 81 have sufficient energy to move to the metal layer 84, thereby producing an electric current. Since the metal layer 84 does not have minor carriers, electric charges cannot be stored. Therefore, the reverse restoring time is very short. According to the above description, the Schottky diode uses the junction between the metal and the semiconductor as the Schottky barrier for current rectification. It is different from the PN junction formed by semiconductor/semiconductor junction in normal diodes. The characteristics of the Schottky barrier render a lower forward voltage drop for the Schottky diode. The voltage drop of normal PN junction diodes is 0.7-1.7 volts. The voltage drop of the Schottky diode is 0.15-0.45 volts. The characteristics of the Schottky barrier also increase the switching speed.

With reference to FIG. 7, the characteristic curve of the Schottky diode shows the relation between the forward voltage V and the current I and relationship between the reverse breakdown voltage and the current I. The characteristic curve indicates that as the current I becomes larger, the forward voltage V also becomes higher. The rise in the forward voltage definitely affects the characteristics and applications of the Schottky diode. According to experimental results, the forward voltage of the Schottky diode is proportional to the thickness D of the N− type doped drift layer 81 under the Schottky barrier 85. As the thickness D of the N− type doped drift layer 81 becomes larger, the forward voltage also becomes higher. On the other hand, as the thickness D of the N− type doped drift layer 81 becomes thinner, the forward voltage also becomes lower.

### SUMMARY OF THE INVENTION

An objective of the invention is to provide a Schottky diode with a low forward voltage drop. The structure of the Schottky diode according to the invention lowers the forward voltage drop thereof without changing its reverse breakdown voltage.

To achieve the above-mentioned objective, the disclosed Schottky diode includes: an N+ type doped layer, an N− type doped drift layer, an oxide layer, and a metal layer. The N− type doped drift layer is formed on the N+ type doped layer and has a first surface formed with a protection ring inside which is a P-type doped area. The oxide layer is formed on the N− type doped drift layer. The metal layer is formed on the oxide layer and the N− type doped drift layer. The contact region between the metal layer and the N− type doped drift layer and the P-type doped area forms a Schottky barrier. The Schottky barrier is under the first surface of the N− type doped drift layer. According to the above-mentioned structure, the height of the Schottky barrier of the Schottky diode is lower than the first surface of the N− type doped drift layer. The thickness of the N− type doped drift layer under the Schottky barrier is thus reduced, thereby lowering the forward voltage drop of the Schottky diode.

### BRIEF DESCRIPTION OF THE DRAWINGS

FIG. 1 is a schematic view of a first embodiment of the Schottky diode in accordance with the present invention;

FIG. 2 shows a part of the structure of the first embodiment of the Schottky diode in accordance with the present invention;

FIG. 3 shows a part of the structure of a second embodiment of the Schottky diode in accordance with the present invention;

FIG. 4 is a schematic view of a conventional Schottky diode;

FIG. 5 shows characteristic curves of the Schottky diodes in accordance with the present invention and the prior art respectively;

FIG. 6 is another structural view of a conventional Schottky diode; and

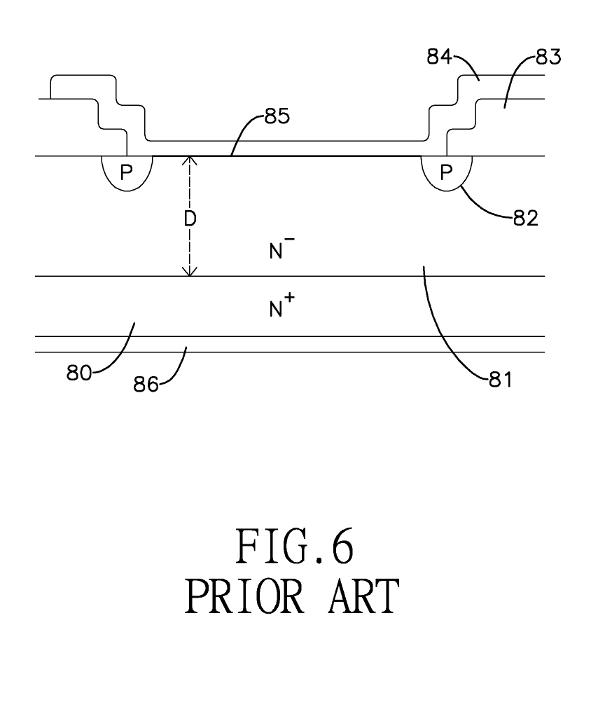

FIG. 7 shows a characteristic curve of a conventional Schottky diode.

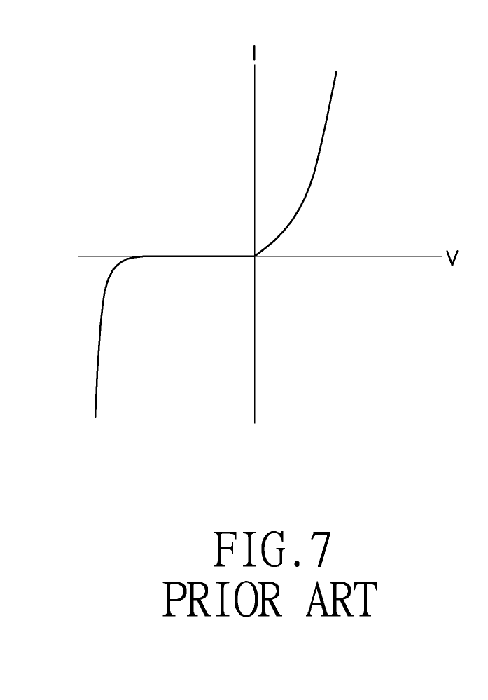

### DETAILED DESCRIPTION OF THE PREFERRED EMBODIMENT

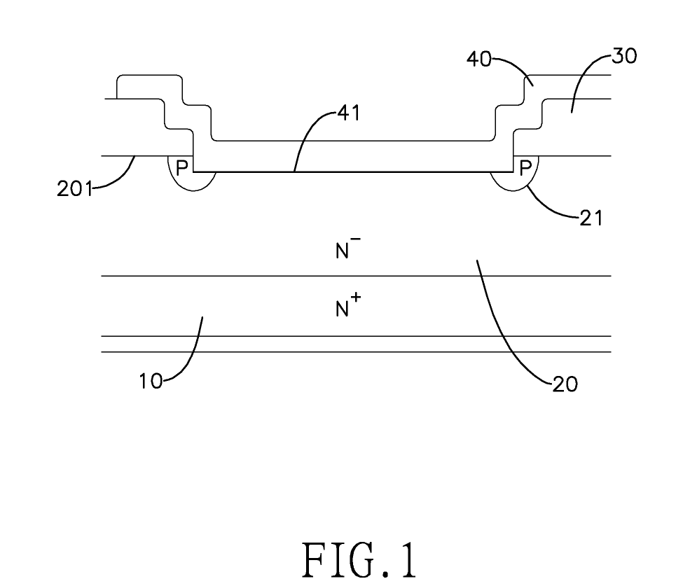

With reference to FIG. 1, a Schottky diode comprises an N− type doped drift layer 20 formed on an N+ type doped layer 10. The N− type doped drift layer 20 has a first surface 201 formed with an embedded protection ring 21 inside which is a P-type doped area. The first surface 201 of the N− type doped drift layer 20 is further formed with an oxide layer 30 that partly covers and touches the P-type doped area in the protection ring 21. Moreover, a metal layer 40 is formed on the N− type doped drift layer 20 and the oxide layer 30. The contact region between the metal layer 40 and the N− type doped drift layer 20 within the P-type doped area forms a Schottky barrier 41.

The invention is characterized in that the Schottky barrier 41 is under the first surface 201 of the N− type doped drift layer 20 to reduce the thickness of the N− type doped drift layer 20 under the Schottky barrier 41. One approach to complete the above-mentioned structure is as follows.

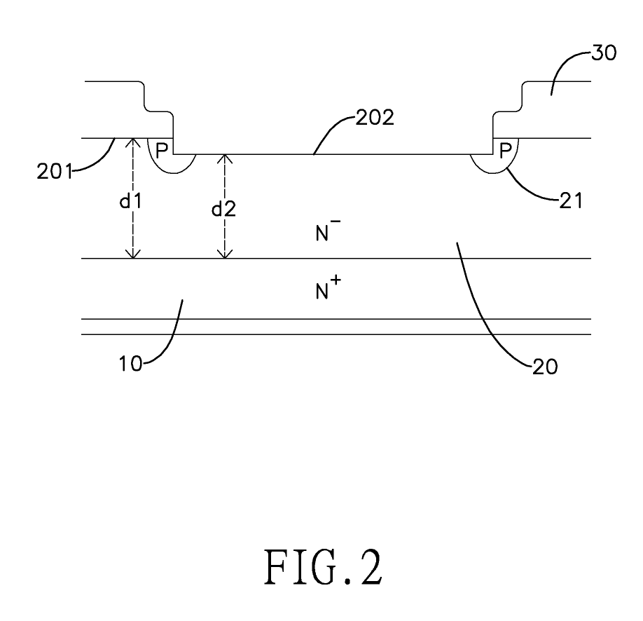

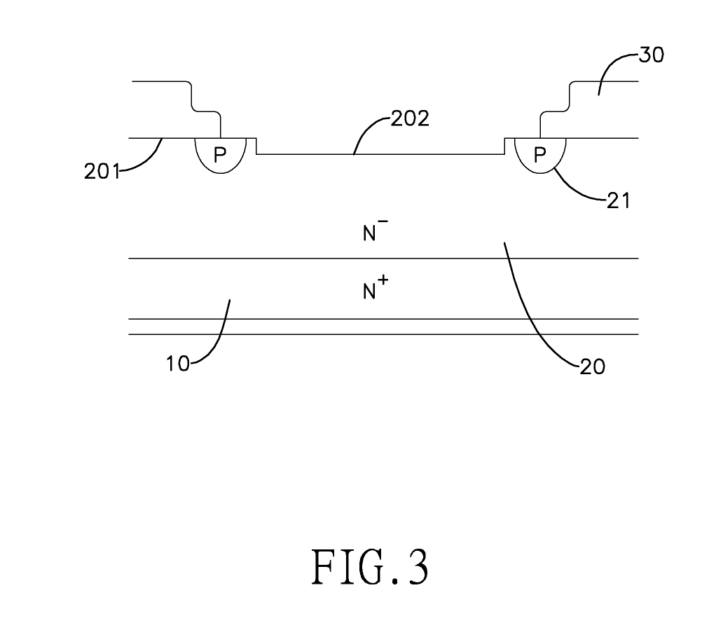

With reference to FIG. 3, before forming the metal layer 40, the region within the protection ring 21 on the N− type doped drift layer 20 is etched so that a second surface 202 lower than the first surface 201 is formed therein. That is, the thickness d1 of the N− type doped drift layer 20 at the first surface 201 is greater than the thickness d2 at the second surface 202. Afterwards, the metal layer 40 is formed on the first and second surfaces 201, 202 of the N− type doped drift layer 20, the P-type doped area, and the oxide layer 30. The contact region between the metal layer 40 and the second surface 202 of the N− type doped drift layer 20 and the P-type doped area forms a Schottky contact, thereby forming a Schottky barrier 41. In this embodiment, the region of the first surface 201 inside the protection ring 21 on the N− type doped drift layer 20 being etched does not include the P-type doped area inside the protection ring 21. With reference to FIG. 2, for convenience, the local region of P-type doped area inside the protection ring 21 can be etched downward as well.

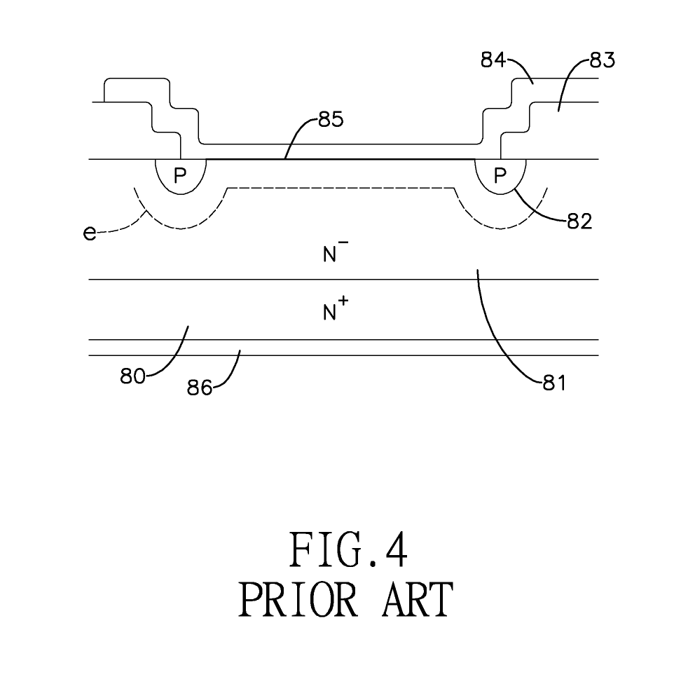

Although the invention reduces the thickness of the N− type doped drift layer 20 under the Schottky barrier 41 to lower the forward voltage drop, the reverse breakdown voltage is guaranteed not to be affected. FIG. 4 is a structural view of a conventional Schottky diode. During reverse restoring, the N− type doped drift layer forms an electric field e under and in the profile of the P-type doped area and the Schottky barrier. After the invention shifts the height of the Schottky barrier downward, the bottom of the electric field e also shifts downward. On the premise of keeping the reverse breakdown voltage invariant, the downward etching depth of the first surface 201 of the N− type doped drift layer 20 follows the principle that the bottom of the electric field e does not extend to the N+ type doped layer.

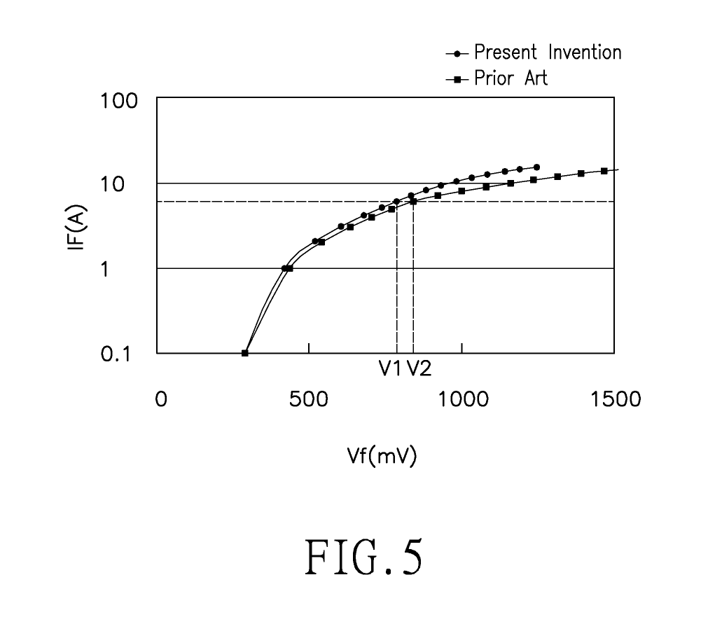

FIG. 5 shows different characteristic curves of Schottky diodes respectively in accordance with the invention and prior art. The characteristic curves show that the forward voltage drop V1 of the invention is smaller than the forward voltage drop V2 of the Schottky diode in the prior art under the same electric current IF.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A Schottky diode with a low forward voltage drop comprising:
an N+ type doped layer;
an N− type doped drift layer formed on the N+ type doped layer and having a first surface formed with a protection ring inside which is a P-type doped area;
an oxide layer formed on the N− type doped drift layer; and
a metal layer formed on the oxide layer and the N− type doped drift layer, wherein a contact region between the metal layer and the N− type doped drift layer and the P-type doped area forms a Schottky barrier that is under the first surface of the N− type doped drift layer.

2. The Schottky diode as claimed in claim 1, wherein a region inside the protection ring is etched before forming the metal layer so that the N− type doped drift layer is formed with a second surface lower than the first surface inside the protection ring, the etched region excluding the P-type doped area.

3. The Schottky diode as claimed in claim 1, wherein a region inside the protection ring is etched before forming the metal layer so that the N− type doped drift layer is formed with a second surface lower than the first surface inside the protection ring, the etched region including a part of the P-type doped area.
